(19) United States
(12) Patent Application Publication
(10) Pub. No.: US 2025/0351549 A1
(43) Pub. Date: Nov. 13, 2025

(54) GATE-ALL-AROUND DEVICES

(71) Applicant: Taiwan Semiconductor Manufacturing Company, Ltd., Hsin-Chu (TW)

(72) Inventors: Yu-Shiang Huang, Hsinchu City (TW); Yen-Ting Chen, Taichung City (TW); Wei-Yang Lee, Taipei City (TW); Yuan-Ching Peng, Hsinchu (TW)

(21) Appl. No.: 19/279,019

(22) Filed: Jul. 24, 2025

Related U.S. Application Data
(63) Continuation of application No. 18/764,951, filed on Jul. 5, 2024.
(60) Provisional application No. 63/551,310, filed on Feb. 8, 2024.

(51) Int. Cl. H10D 84/03; H01L 21/762; H10D 30/01; H10D 30/43; H10D 30/67; H10D 62/10; H10D 62/832; H10D 64/01; H10D 64/23; H10D 84/01; H10D 84/85

(52) U.S. Cl. CPC H10D 84/038; H01L 21/76224; H10D 64/015; H10D 84/0188; H10D 84/859; H10D 30/014; H10D 30/43; H10D 30/6735; H10D 30/6757; H10D 62/121; H10D 62/832; H10D 64/258

(57) ABSTRACT

Semiconductor structures and processes for forming the same provided. A semiconductor structure according to the present disclosure includes an insolation feature, a first base fin and a second base fin extending through and rising above the isolation feature, a first active region disposed over the first base fin, a second active region disposed over the second base fin, a gate structure disposed over the first active region, the second active region, and the isolation feature, and a protection layer sandwiched between the gate structure and the isolation feature.

### PRIORITY DATA

This application is a continuation application of U.S. patent application Ser. No. 18/764,951, filed Jul. 5, 2024, which claims priority to U.S. Provisional Patent Application No. 63/551,310, filed Feb. 8, 2024, each of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-24 illustrate fragmentary cross-sectional views of a work-in-progress (WIP) structure during a fabrication process according to the method of FIG. 1, according to one or more aspects of the present disclosure.

FIG. 25 illustrates a flowchart of a method to form a protection structure for an isolation feature, according to one or more aspects of the present disclosure.

FIGS. 26-34 illustrate fragmentary cross-sectional views of a work-in-progress (WIP) structure during a fabrication process according to the method of FIG. 25, according to one or more aspects of the present disclosure.

FIG. 35 illustrates a flowchart of a method to form a protection structure for an isolation feature, according to one or more aspects of the present disclosure.

FIGS. 36-43 illustrate fragmentary cross-sectional views of a work-in-progress (WIP) structure during a fabrication process according to the method of FIG. 35, according to one or more aspects of the present disclosure.

FIG. 44 illustrates a flowchart of a method to form a protection structure for an isolation feature, according to one or more aspects of the present disclosure.

FIGS. 45-55 illustrate fragmentary cross-sectional views of a work-in-progress (WIP) structure during a fabrication process according to the method of FIG. 44, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed. As used herein, a source/drain region, or “S/D region,” may refer to a region that provides a source and/or drain for one or multiple devices. It may also refer to a source or a drain of one or multiple devices.

The present disclosure is generally related to GAA transistors and fabrication methods thereof. GAA transistors may be fabricated using a replacement gate process, where a dummy gate stack is formed first as a placeholder and is later on replaced with a functional gate structure. In some replacement gate processes, an isolation feature between two adjacent fin-shaped structures may be subject to more than one etch processes and suffer from substantial loss. The overly recessed isolation feature may result in electrical short between a source/drain contact and increase in parasitic capacitance and parasitic current.

The present disclosure provides methods for forming a GAA transistor. In an example, a protection layer is deposited over a top surface of the isolation feature before the formation of a dummy gate stack over a channel region of a fin-shaped active region. The fin-shaped active region includes a plurality of channel layers interleaved by a plurality of sacrificial layers. After formation of at least one gate spacer over the dummy gate stack and recessing of source/drain regions of the fin-shaped active region, the plurality of sacrificial layers in the channel regions are selectively removed to release the plurality of channel layers as channel members. A dielectric dummy layer is then deposited to wrap around each of the channel members. The dielectric dummy layer is then selectively and partially recessed to form inner spacer recesses between the plurality of channel members. Inner spacer features are then formed in the inner spacer recesses. Thereafter, source/drain features are formed over the source/drain recesses to engage sidewalls of the channel members. The dummy gate stack and the dummy layer are then removed and replaced with a functional gate structure. The protection layer protects the isolation feature from being excessively etched.

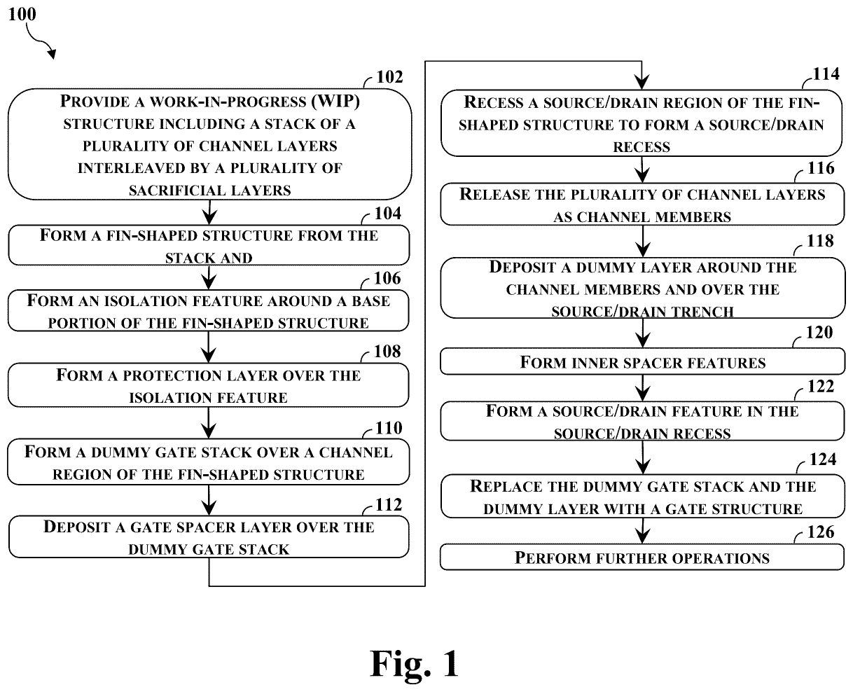

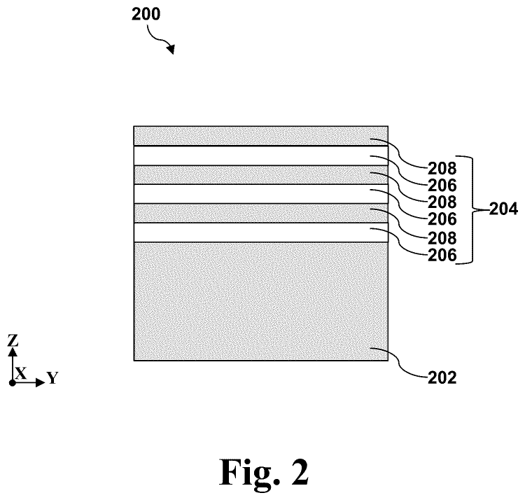

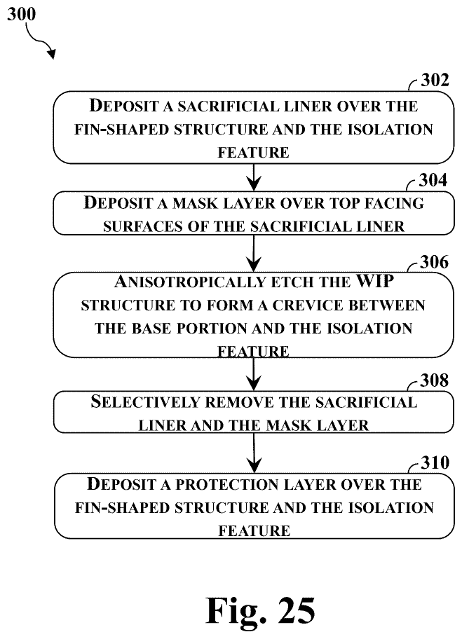

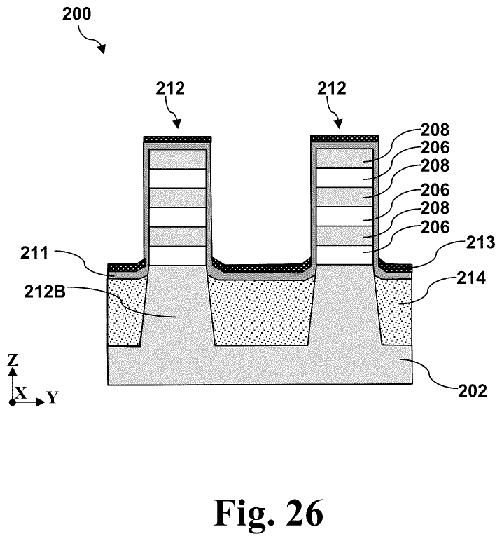

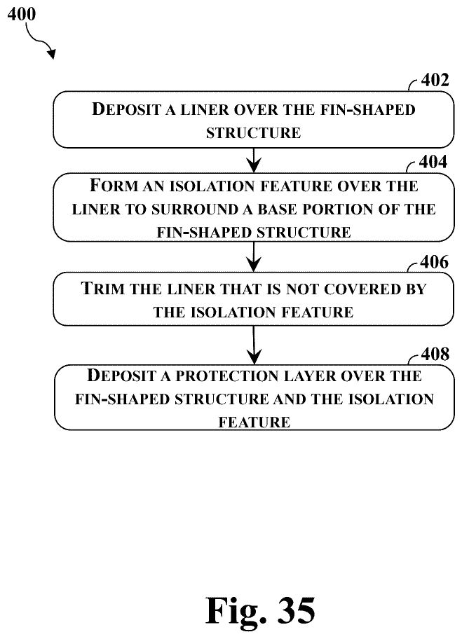

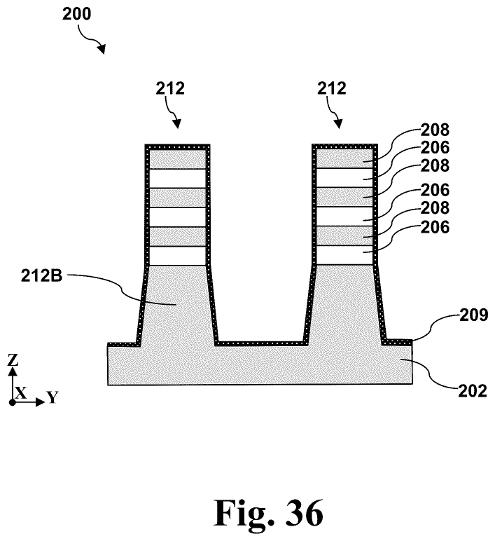

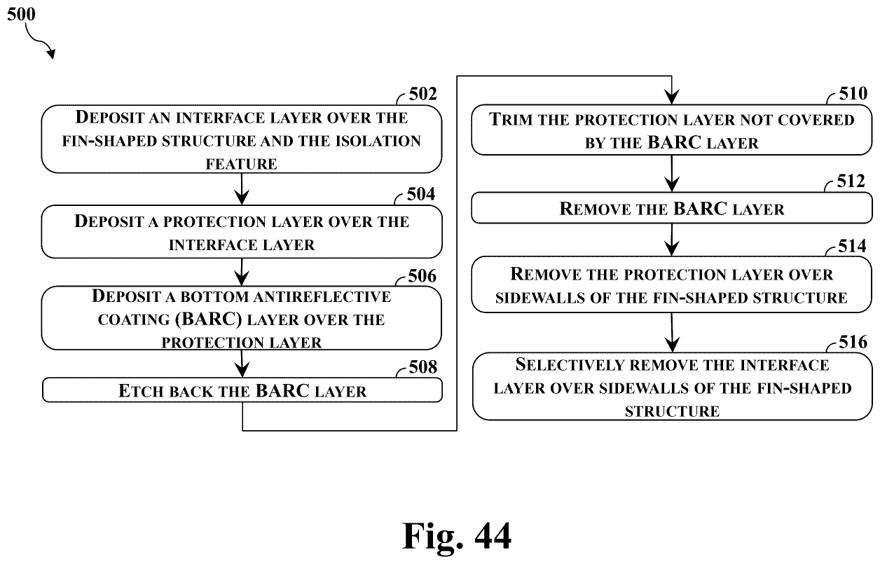

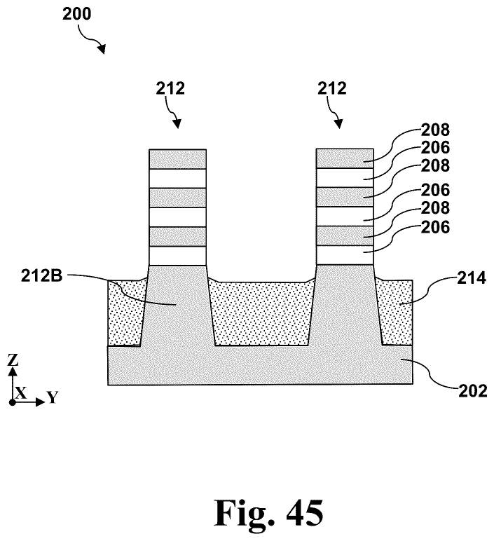

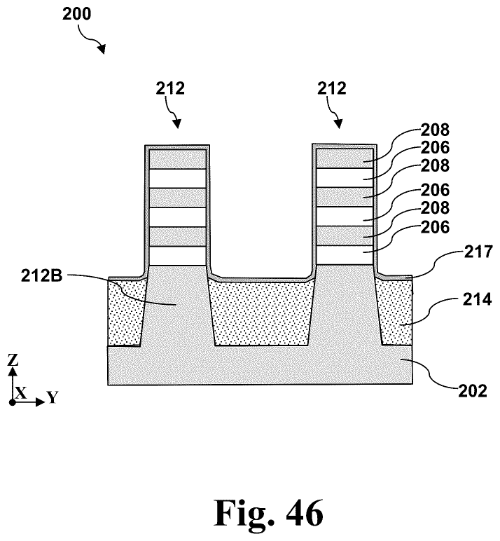

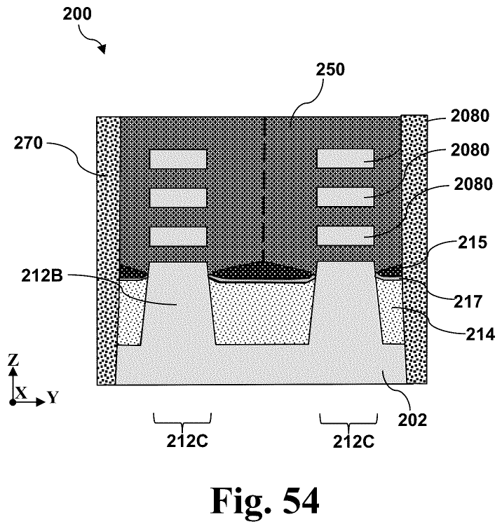

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 includes operations to form a protection layer over an isolation feature and FIGS. 25, 35 and 44 are flowcharts illustrating methods 300, 400 and 500 of forming alternative protection layers or protection structures to protect the isolation feature. Method 300, 400 and 500 are compatible with and may be integrated in method 100. Methods 100, 300, 400, and 500 are merely examples and are not intended to limit the present disclosure to what is explicitly illustrated in method 100, 300, 400, and 500. Additional steps can be provided before, during and after method 100, 300, 400, or 500, and some steps described can be replaced, eliminated, or moved around for additional embodiments of the method. Not all steps are described herein in detail for reasons of simplicity. Method 100 is described below in conjunction with FIG. 2-24, which are fragmentary cross-sectional views of a WIP structure at different stages of fabrication according to embodiments of the method 100 in FIG. 1. Method 300 is described below in conjunction with FIGS. 26-34, which are fragmentary cross-sectional views of a WIP structure at different stages of fabrication according to embodiments of the method 300 in FIG. 25. Method 400 is described below in conjunction with FIGS. 36-43, which are fragmentary cross-sectional views of a WIP structure at different stages of fabrication according to embodiments of the method 400 in FIG. 35. Method 500 is described below in conjunction with FIGS. 45-55, which are fragmentary cross-sectional views of a WIP structure at different stages of fabrication according to embodiments of the method 500 in FIG. 44. Because the WIP structure 200 will be fabricated into a semiconductor structure or a semiconductor device, the WIP structure 200 may be referred to herein as a semiconductor structure or a semiconductor device 200 as the context requires. For avoidance, the X, Y and Z directions in FIGS. 2-24, 26-34, 36-43, and 45-55 are perpendicular to one another. Throughout the present disclosure, unless expressly otherwise described, like reference numerals denote like features or steps.

Referring to FIGS. 1 and 2, method 100 includes a block 102 where a stack 204 of alternating semiconductor layers is formed over the WIP structure 200. As shown in FIG. 2, the WIP structure 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

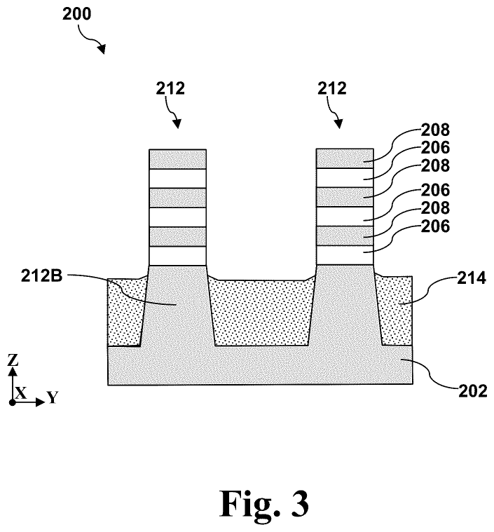

Referring to FIGS. 1 and 3, method 100 includes a block 104 where a fin-shaped structure 212 is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202 and the patterned stack 204 disposed directly over the base fin structure 212B.

Referring to FIGS. 1 and 3, method 100 includes a block 106 where an isolation feature 214 is formed around a base portion of the fin-shaped structures 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

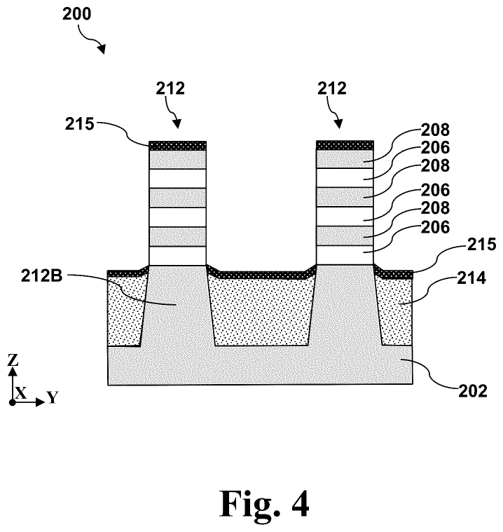

Referring to FIGS. 1, 4 and 5, method 100 includes a block 108 where a protection layer 215 is formed over the isolation feature 214. In some embodiments, the protection layer 215 includes silicon nitride, silicon oxycarbonitride, aluminum oxide, or a combination thereof. When the protection layer 215 includes silicon nitride, the protection layer 215 may exert tensile strain and may have a dielectric constant between about 6 and about 7. When the protection layer 215 includes silicon oxycarbonitride, the protection layer 215 may have a dielectric constant smaller than 6. When the protection layer 215 includes silicon oxycarbonitride, a silicon content in the protection layer 215 may be between about 20% and about 40%, an oxygen content in the protection layer 215 may be greater than 30%, a carbon content in the protection layer 215 may be smaller than 30%, and a nitrogen content in the protection layer 215 may be smaller than 25%. In some embodiments represented in FIG. 4, the protection layer 215 may be deposited on top facing surfaces, such as top surfaces of the isolation feature 214 and the fin-shaped structures 212, using a combination of a deposition process and an etch back process. The protection layer 215 may be first deposited using a physical vapor deposition (e.g., sputtering) or chemical vapor deposition. Because the top facing surfaces are more in the line of sight, the deposited protection layer 215 is thicker on the top facing surfaces and thinner along the sidewalls of the fin-shaped structures 212. After the deposition, the deposited protection layer 215 is etched back until the protection layer 215 along sidewalls of the fin-shaped structures 212 is removed. The etching back may be performed using an isotropic etch process, such as a wet etch process that uses phosphoric acid. In some implementations, a thickness of the protection layer 215 may be between about 0.5 nm and about 3 nm.

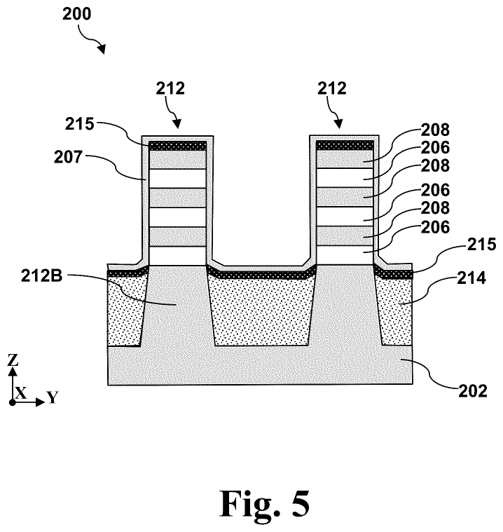

In some embodiments represented in FIG. 5, after the formation of the protection layer 215 over the isolation feature 214, a silicon liner 207 may be deposited over the WIP structure 200, including over the protection layer 215 and along sidewalls of the fin-shaped structure 212. The silicon liner 207 functions to protect the sidewalls of the sacrificial layers 206 as they can sustain undesirable damages during the fabrication processes. In some implementations, the silicon liner 207 may be deposited using PVD, CVD, or atomic layer deposition (ALD).

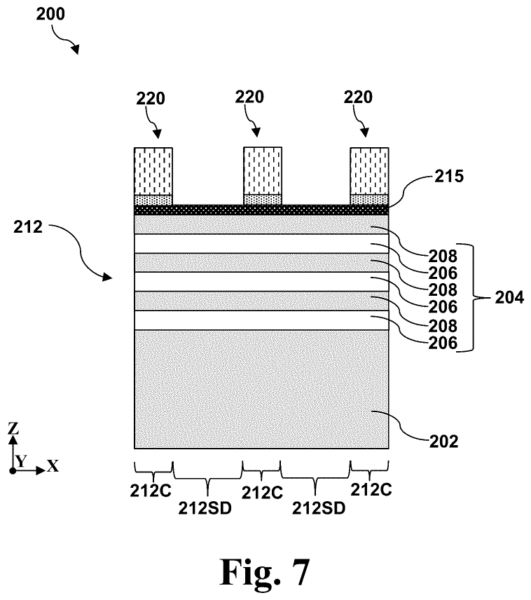

Referring to FIGS. 1, 6 and 7, method 100 includes a block 110 where a dummy gate stack 220 is formed over a channel region 212C of the fin-shaped structure 212. The dummy gate stack 220 serves as a placeholder to undergo various processes and is to be removed and replaced by a functional gate structure. Other processes and configuration are possible. In some embodiments illustrated in FIG. 7, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent the source/drain regions 212SD. As shown in FIG. 7, the channel region 212C is disposed between two source/drain regions 212SD along the X direction.

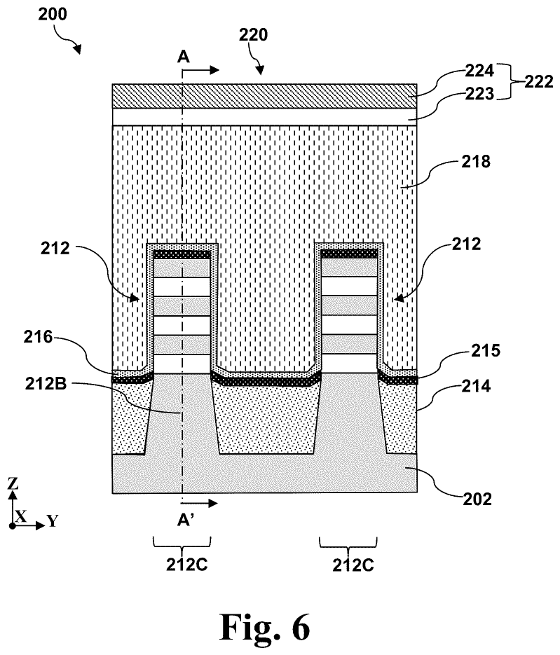

The formation of the dummy gate stack 220 may include deposition of layers in the dummy gate stack 220 and patterning of these layers. Referring to FIG. 6, a dummy dielectric layer 216, a dummy electrode layer 218, and a gate-top hard mask layer 222 may be blanketly deposited over the WIP structure 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidize the silicon liner 207 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 7. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 7, the dummy gate stack 220 is patterned such that it is only disposed over the channel region 212C, not disposed over the source/drain region 212SD.

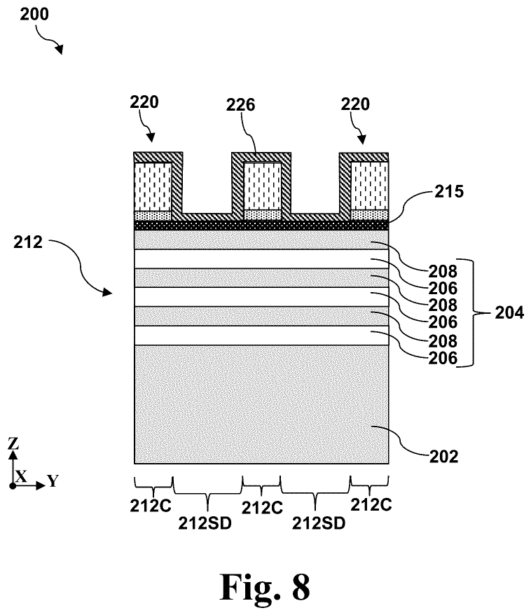

Referring to FIGS. 1 and 8, method 100 includes a block 112 where a gate spacer layer 226 is deposited over the WIP structure 200, including over the dummy gate stack 220. In some embodiments, the gate spacer layer 226 is deposited conformally over the WIP structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

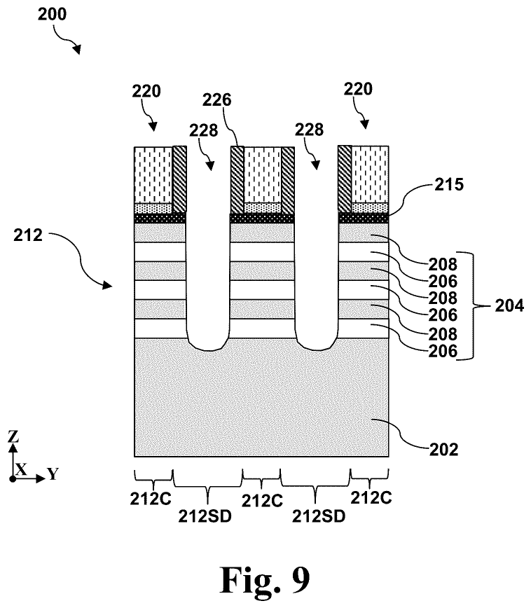

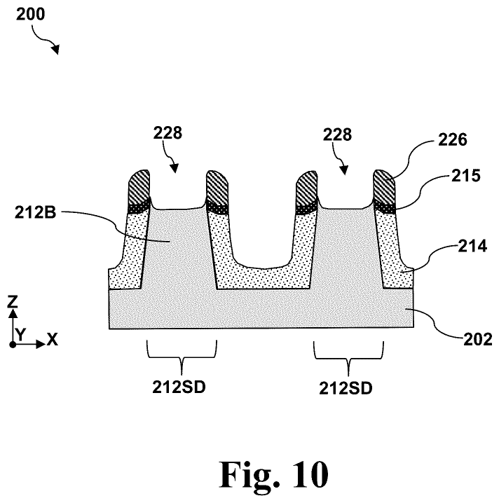

Referring to FIGS. 1, 9 and 10, method 100 includes a block 114 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 9, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Reference is made to FIG. 10, which includes a fragmentary cross-sectional view across two adjacent source/drain regions 212SD. As shown in FIG. 10, over the source/drain regions 212SD, the majority of the fin-shaped structure 212 is etched away and a top surface of the base fin structure 212B is exposed in the source/drain region 212SD. Because the gate spacer layer 226 etches at a slower rate than the fin-shaped structure 212, the gate spacer layer 226 in the source/drain region 212SD rises above the top surface of the base fin structure 212B. In some instances, a top surface of the protection layer 215 under the gate spacer layer 226 may also be higher than the top surface of the base fin structure 212B in the source/drain region 212SD.

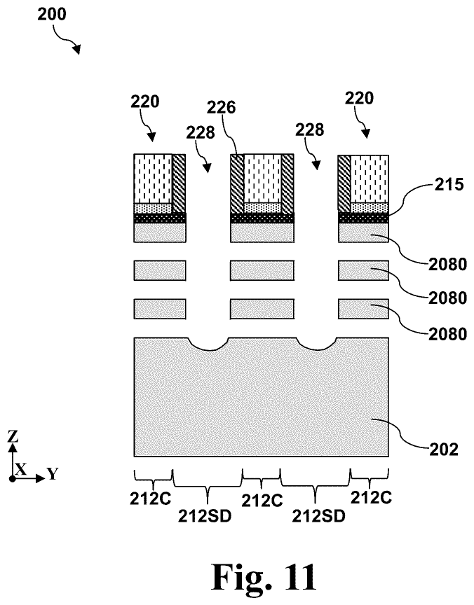

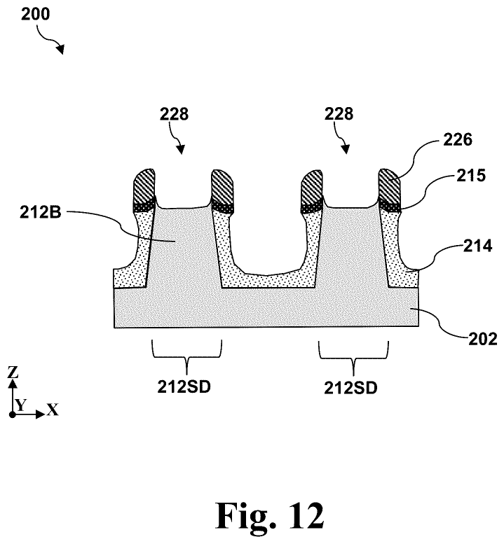

Referring to FIGS. 1, 11 and 12, method 100 includes a block 116 where the plurality of channel layers 208 in the channel regions are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 9) to form channel members 2080 shown in FIG. 11. The selective removal of the sacrificial layers 206 forms spaces between and around adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). At block, the source/drain regions 212SD, shown in FIG. 12, are not substantially etched.

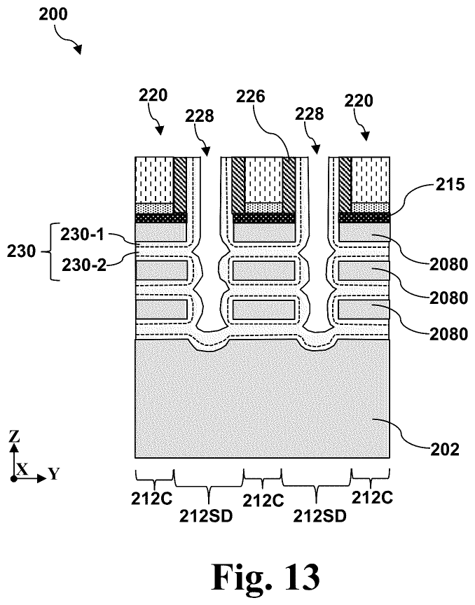

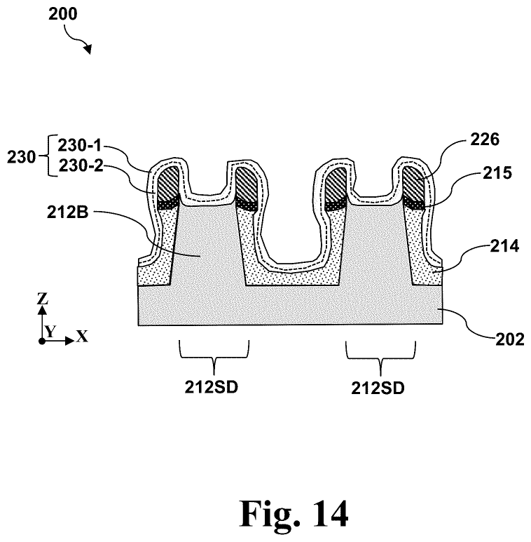

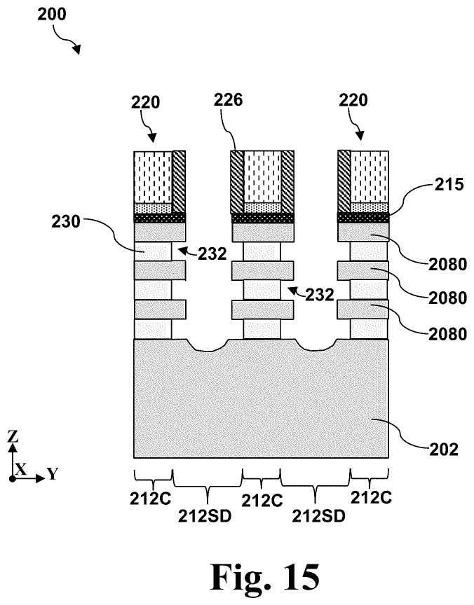

Referring to FIGS. 1, 13 and 14, method 100 incudes a block 118 where a dummy layer 230 is deposited around the channel members 2080 and over the source/drain trenches 228. The dummy layer 230 may include silicon oxide and may be deposited using one or more deposition methods that are performed under low temperature (i.e., lower than about 100° C.). In an example process depicted in FIGS. 13 and 14, a first dummy layer 230-1 is first deposited using atomic layer deposition (ALD) at a temperature between about 10° C. and about 30° C. to reach a thickness between about 10 Å and about 20 Å. The ALD deposition of the first dummy layer 230-1 is conformal and functions to reduce loading effect caused by width variation in the active region. Then a second dummy layer 230-2 is deposited using flowable chemical vapor deposition (FCVD) at a temperature between about 20° C. and about 100° C. to reach a thickness between about 70 Å and about 120 Å. In some instances, reactants used in the FCVD process may include trisilylamine (TSA), ammonia, oxygen, or a combination thereof. The presence of the amine or ammonia improves bonding and prevents void and seam. To replace nitrogen atoms in the deposited second dummy layer 230-2, ozone may be used in an oxidation process at a temperature between about 8° C. and about 40° C. To improve quality of the second dummy layer 230-2 and to remove silicon-hydrogen bond, an ultraviolet (UV) curing process may also be performed after the oxidation process. The UV curing process may be performed at a temperature between about 8° C. and about 40° C. The first dummy layer 230-1 and the second dummy layer 230-2 shown in FIGS. 13 and 14 may be collectively referred to as the dummy layer 230. In some alternative embodiments, the dummy layer 230 may be formed using ALD only. For ease of illustration, the dummy layer 230 is show as a single layer in FIGS. 15-18. The low-temperature deposition process prevents damages to the channel members 2080 and still ensures consistency for uniform etching characteristics. As shown in FIG. 13, the dummy layer 230 fills the space among the channel members 2080 and covers end sidewalls of the channel members 2080. Additionally, the dummy layer 230 is in direct contact with a sidewall of the gate spacer layer 226, a sidewall of the protection layer 215, and a top surface of the substrate 202. Reference is made to FIG. 14, which includes a fragmentary cross-sectional view across two adjacent source/drain regions 212SD. As shown in FIG. 14, the dummy layer 230 extends conformally over the isolation feature 214, sidewalls of the protection layer 215, sidewalls of the gate spacer layer 226, and top surfaces of the gate spacer layer 226. Depending on the design, the channel members 2080 may take form of nanowires, nanosheets, or other nanostructures.

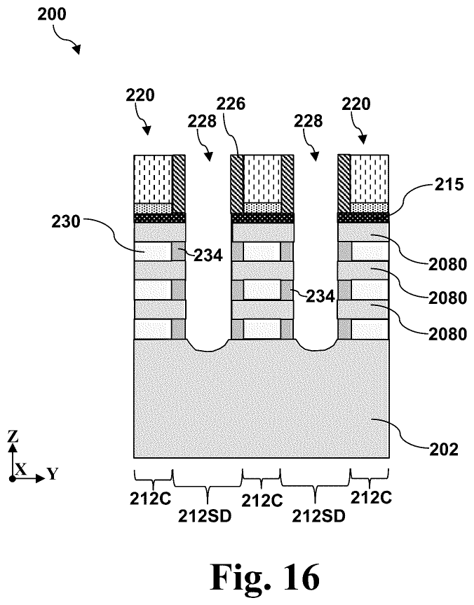

Referring to FIGS. 1, 15, 16, and 17, method 100 includes a block 120 where inner spacer features 234 are formed. While not shown explicitly, operation at block 120 may include selective and partial removal of the dummy layer 230 to form inner spacer recesses 232 (shown in FIG. 15), deposition of inner spacer material over the WIP structure 200, and etching back the inner spacer material to form inner spacer features 234 in the inner spacer recesses 232 (shown in FIG. 16). Referring to FIG. 15, the dummy layers 230 are selectively and partially recessed to form inner spacer recesses 232 while the gate spacer layer 226, the dummy gate stack 220, the exposed portion of the substrate 202, and the channel layers 208 are substantially unetched. In an embodiment where the channel layers 208 consist essentially of silicon (Si) and the dummy layers 230 are formed of silicon oxide, the selective recess of the dummy layer 230 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

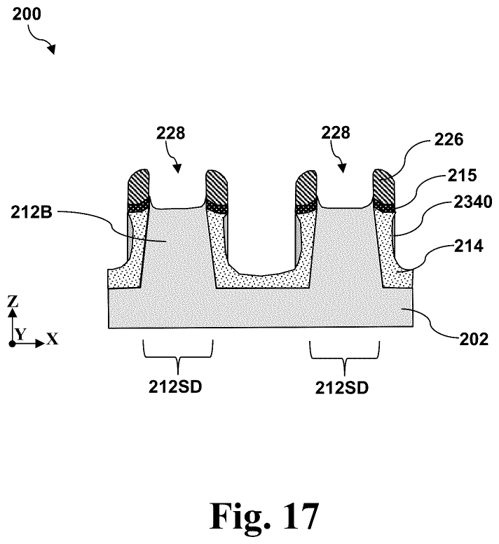

After the inner spacer recesses 232 are formed, an inner spacer material is deposited over the WIP structure 200, including over the inner spacer recesses 232. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 232 as well as over the sidewalls of the channel layers 208 exposed in the source/drain trenches 228. Referring to FIG. 16, the deposited inner spacer material is then etched back to remove the inner spacer material from the sidewalls of the channel members 2080 to form the inner spacer features 234 in the inner spacer recesses 232. Reference is made to FIG. 17, which includes a fragmentary cross-sectional view across two adjacent source/drain regions 212SD. As shown in FIG. 17, the etch back may not completely remove a sidewall portion 2340 of the inner spacer feature 234 along sidewalls of the isolation feature 214.

Referring to FIGS. 1, 18 and 19, method 100 includes a block 122 where a source/drain feature 240 is formed over the source/drain region 212D. While not explicitly shown, before any of the epitaxial layers are formed, method 100 may include a cleaning process to clean surfaces of the WIP structure 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

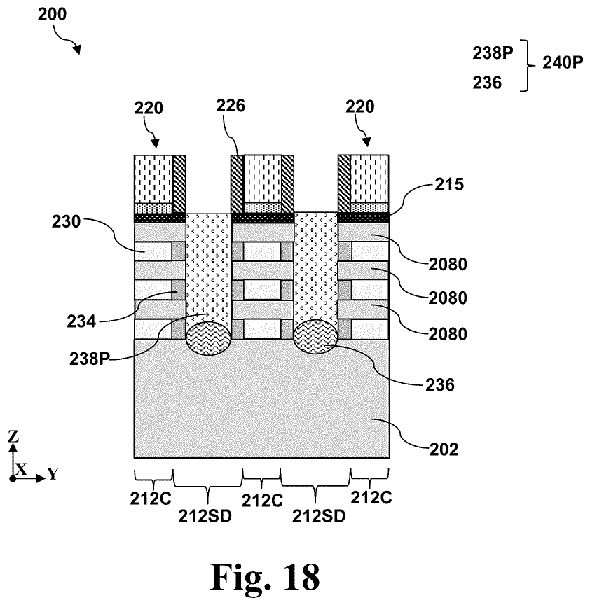

Reference is made to FIG. 18. The source/drain feature 240 may be an n-type source/drain feature 240N or a p-type source/drain feature 240P. When the source/drain feature 240 is an n-type source/drain feature 240N, it includes a bottom epitaxial feature 236 and at least one n-type doped epitaxial layer 238N over the bottom epitaxial feature 236. The at least one n-type doped epitaxial layer 238N may include an n-type dopant, such as phosphorus (P), arsenic (As), antimony (Sb), or a combination thereof. When the source/drain feature 240 is a p-type source/drain feature 240P, it includes a bottom epitaxial feature 236 and at least one p-type doped epitaxial layer 238P over the bottom epitaxial feature 236. The at least one p-type doped epitaxial layer 238P may include a p-type dopant, such as phosphorus (P), arsenic (As), or antimony (Sb). In some embodiments, the bottom epitaxial feature 236 may include an undoped semiconductor material, such as undoped silicon (Si) or undoped silicon germanium (SiGe). As used herein, the undoped semiconductor material is regarded as undoped when it is not intentionally doped. In some alternative embodiments, the bottom epitaxial feature 236 may include a counter dopant to reduce leakage into the bulk substrate 202. For example, the bottom epitaxial feature 236 in the n-type source/drain feature 240N may include a p-type dopant, such as boron (B). For another example, the bottom epitaxial feature 236 in the p-type source/drain feature 240P may include an n-type dopant, such as phosphorus (P), arsenic (As), or antimony (Sb). The source/drain feature 240 may be formed using vapor-phase epitaxy (VPE), ultra-high vacuum CVD (UHV-CVD), or molecular beam epitaxy (MBE). Doping of the source/drain features 240 may be achieved with in-situ doping.

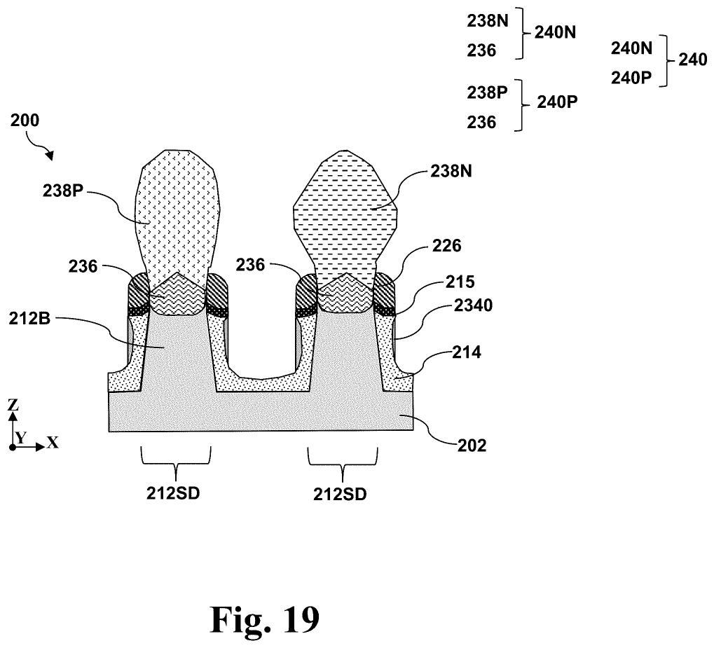

Reference is made to FIG. 19, which includes a fragmentary cross-sectional view across two adjacent source/drain regions 212SD. In some embodiments represented in FIG. 19, an n-type source/drain feature 240N may be adjacent a p-type source/drain feature 240P. Each of the n-type source/drain feature 240N and the p-type source/drain feature 240P may be in direct contact with a top surface of the base fin structure 212B, a sidewall of the protection layer 215, and a sidewall of the gate spacer layer 226.

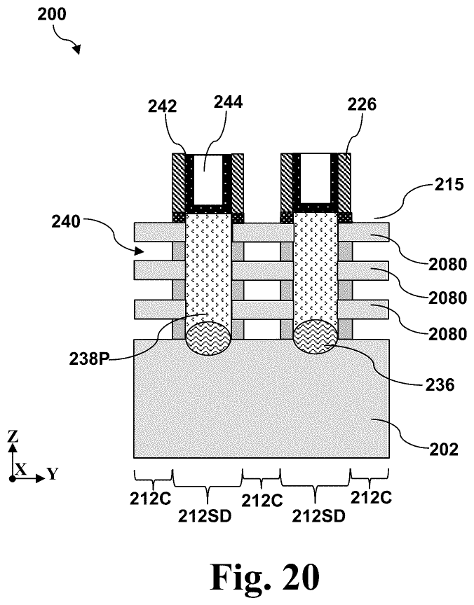

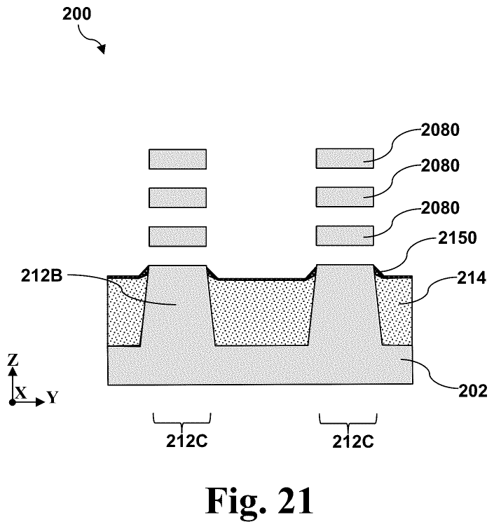

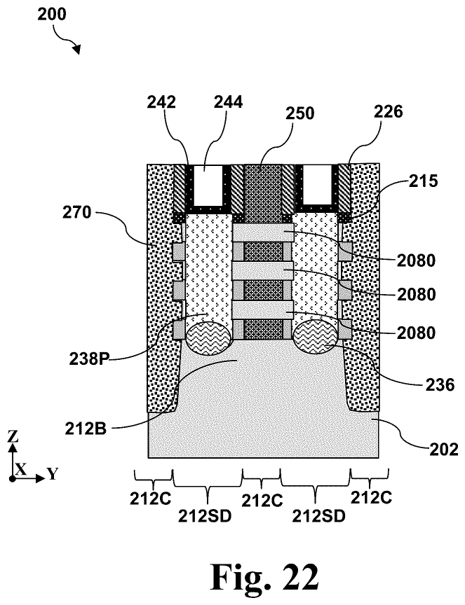

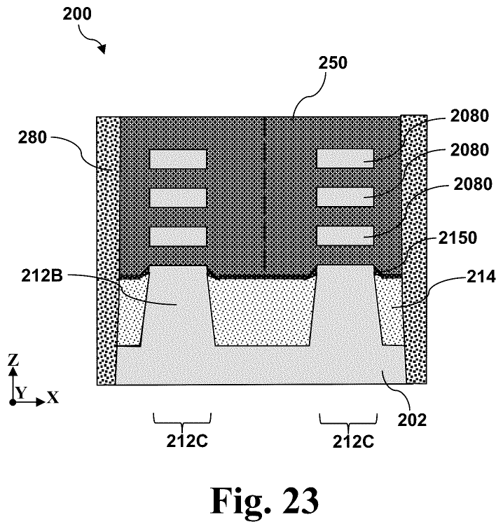

Referring to FIGS. 1 and 20-23, method 100 includes a block 124 where the dummy gate stack 220 and the dummy layer 230 are replaced with a gate structure 250. Operations at block 124 may include deposition of a contact etch stop layer (CESL) 242 over the source/drain features 240 (shown in FIG. 20), deposition of an interlayer dielectric layer 244 over the CESL 242 (shown in FIG. 20), removal of the dummy gate stack 220 and the dummy layer 230 (shown in FIGS. 20 and 21), and deposition of the gate structure 250 to wrap around each of the channel members 2080 (shown in FIGS. 22 and 23). Referring to FIG. 20, the CESL 242 is deposited over the WIP structure 200, including over the source/drain feature 240. The CESL 242 may include silicon nitride or aluminum nitride. In some implementations, the CESL 242 may be deposited using CVD or atomic layer deposition (ALD). The ILD layer 244 is then deposited over the CESL 242. In some embodiments, the ILD layer 244 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be deposited using CVD, flowable CVD (FCVD), spin-on coating, or a suitable deposition technique. After the deposition of the ILD layer 244, the WIP structure 200 may be planarized by a planarization process to expose the dummy gate stack 220. For example, the planarization process may include a chemical mechanical planarization (CMP) process. Exposure of the dummy gate stack 220 allows the removal of the dummy gate stack 220. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, the dummy layer 230 in the channel region 212C is exposed. A separate etch process may be performed to selectively remove the dummy layer 230 in the channel region 212C. After the selective removal of the dummy layer 230, the channel members 2080 in the channel region 212C are once again exposed. In some embodiments represented in FIG. 21, while the removal of the dummy gate stack 220 substantially removes the protection layer 215 over top surfaces of the topmost channel members 2080, a bottom protection layer 2150 may remain. To prevent damages to the channel members 2080, the removal of the dummy gate stack 220 is only performed until the topmost channel members 2080 are no longer covered by the protection layer 215. However, the protection layer 215 over the isolation feature 214, especially at the corner of the base fin structure 212B and the isolation feature 214, may undergo slower etching and may remain, forming the bottom protection layer 2150. It is noted that the bottom protection layer 2150 may be thicker around the corner of the base fin structure 212B and the isolation feature 214.

After the release of the channel members 2080, the gate structure 250 is formed to wrap around each of the channel members 2080 as shown in FIGS. 22 and 23. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure includes portions that interpose between channel members 2080 in the channel region 212C. In some embodiments, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080. The gate structure 250 in FIG. 23 includes the p-type gate structure portion and the n-type gate structure portion disposed side-by-side. As indicated by a dotted line in FIG. 23, the p-type gate structure portion wraps around a stack of channel members 2080 and the n-type gate structure portion wraps around another stack of channel members 2080. In some embodiments represented in FIG. 23, the gate structure 250 is disposed over and in contact with the bottom protection layer 2150.

In some embodiments represented in FIG. 22, dielectric gate structures 270 may be formed to isolate the semiconductor device 200 from adjacent devices along the gate-length direction (i.e., the Y direction). To form the dielectric gate structures 270, a trench recess is formed to vertically extend into the base fin structure 212B. A dielectric material is deposited over the trench recess and then planarized to for the dielectric gate structures 270. In some instances, the dielectric gate structures 270 may include silicon nitride, silicon oxycarbonitride, or a combination thereof. In some embodiments represented in FIG. 23, dielectric fins 280 may be formed to isolate the gate structure 250 from adjacent devices along the gate-width direction (i.e., the X direction). In some instances, the dielectric fins 280 may include silicon nitride, silicon oxycarbonitride, or a combination thereof.

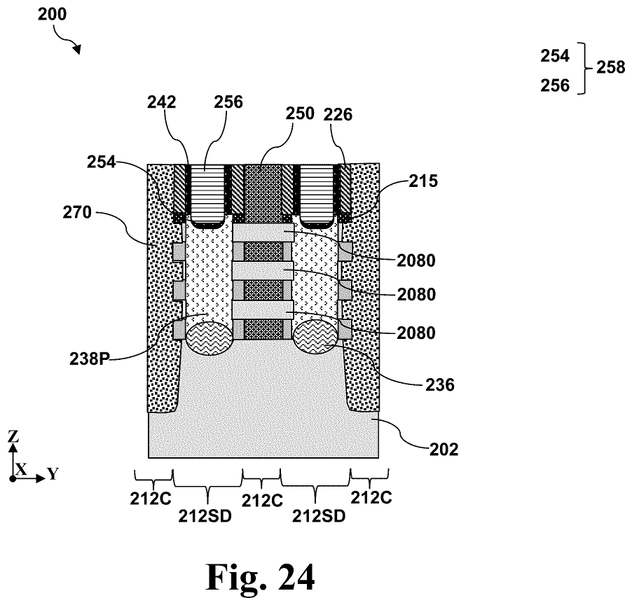

Referring to FIGS. 1 and 24, method 100 includes a block 126 where further processes are performed. Such further processes may include, for example, formation of a source/drain contact 258 to the source/drain feature 240 (including the n-type source/drain feature 240N and the p-type source/drain feature 240P). To form the source/drain contact 258, a contact opening is formed through the CESL 242 and the ILD 244 to expose the source/drain feature 240. The source/drain contact 258 includes an silicide feature 254 to interface the source/drain feature 240 and a metal fill layer 256 disposed over the silicide feature 254. In an example process, a silicide feature 254 is first formed over the exposed surface of the source/drain feature 240 and then a metal fill layer 256 is deposited over the silicide feature 254. In some implementations, the silicide feature 254 may include titanium (Ti), titanium nitride (TiN), tantalum (Ta), or tantalum nitride (TaN) and the metal fill layer 256 may include cobalt (Co), tungsten (W), or copper (Cu).

Method 100 includes block 108 to form the protection layer 215 on top surfaces of the isolation feature 214. The protection layer 215 formed in method 100 protects the top surfaces of the isolation feature 214 but may not protect sidewalls of the isolation feature 214. Method 300 in FIG. 25 includes operations that replace block 108 such that the protection layer 215 includes a sidewall protection layer 215S to partially cover sidewalls of the isolation feature 214.

Referring to FIGS. 25 and 26, method 300 includes a block 302 where a sacrificial liner 211 is deposited over the fin-shaped structure 212 and the isolation feature 214. The sacrificial liner 211 is formed of a dielectric material different from that of the isolation feature 214 and a mask layer 213 to be deposited over the sacrificial liner 211. In one embodiment, the sacrificial liner 211 includes aluminum oxide. At block 302, the sacrificial liner 211 may be conformally deposited over the isolation feature 214 and surfaces of the fin-shaped structures 212 using CVD or ALD. In one embodiment, the sacrificial liner 211 is deposited using ALD.

Referring to FIGS. 25 and 26, method 300 includes a block 304 where a mask layer 213 is deposited over top facing surfaces of the sacrificial liner 211. In some embodiments, the mask layer 213 includes silicon nitride. In some embodiments represented in FIG. 26, the mask layer 213 may be deposited on top facing surfaces of the sacrificial liner 211 using a combination of a deposition process and an etch back process, similar to what is used to deposit the protection layer 215 at block 108 of method 100. In some instances, the mask layer 213 may be deposited using sputtering. That is, the mask layer 213 does not cover the sacrificial liner 211 disposed along sidewalls of the fin-shaped structures 212.

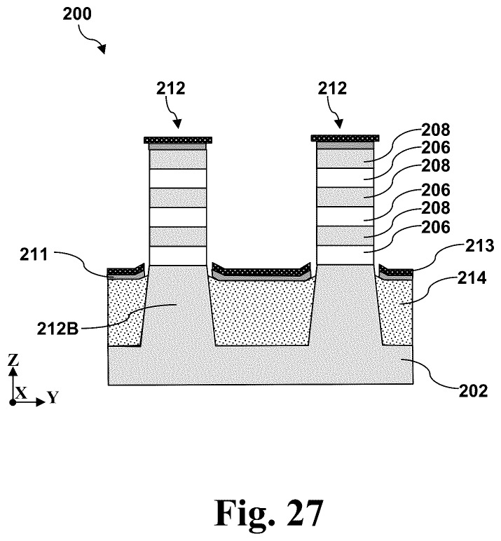

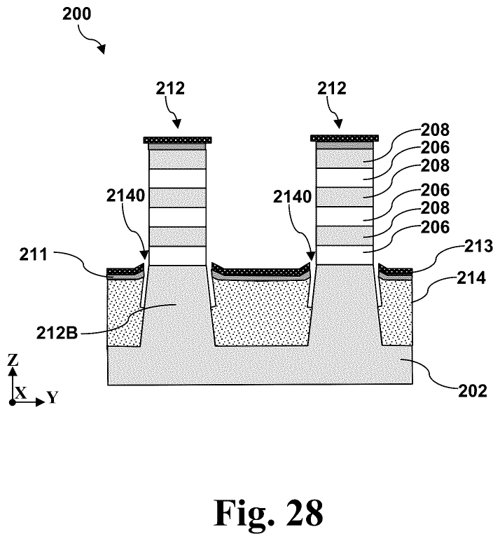

Referring to FIGS. 25, 27 and 28, method 300 includes a block 306 where the WIP structure 200 is etched to form a crevice 2140 between the base fin structure 212B and the isolation feature 214. Operations at block 306 may include selective etching of the sacrificial liner 211 to expose a portion of the isolation feature 214 (shown in FIG. 27) and anisotropic etching of the isolation feature 214 to form the crevice 2140 (shown in FIG. 28). Referring to FIG. 27, the sacrificial liner 211 may be subject to a selective etch process such that portions of the sacrificial liner 211 not covered by the mask layer 213 are selectively removed. An example selective etch process may include use of plasma of boron trichloride (BCl₃) and chlorine (Cl₂), an ammonium hydroxide (NH₄OH) solution, or a mixture of ammonium hydroxide, hydrogen peroxide and water. When the ammonium hydroxide solution or a mixture containing it is used, the process temperature may be greater than room temperature but lower than a boiling point of water, such as between 45° C. and about 70° C. As shown in FIG. 27, the removal of the sacrificial liner 211 along sidewalls of the fin-shaped structures 212 exposes a portion of the isolation feature 214 near the base fin structures 212B. Referring to FIG. 28, with the portions of the isolation feature 214 exposed, an anisotropic etch process is performed to etch the isolation feature 214 until the crevices 2140 are formed. The anisotropic etch process may include a dry etch process that implements an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof.

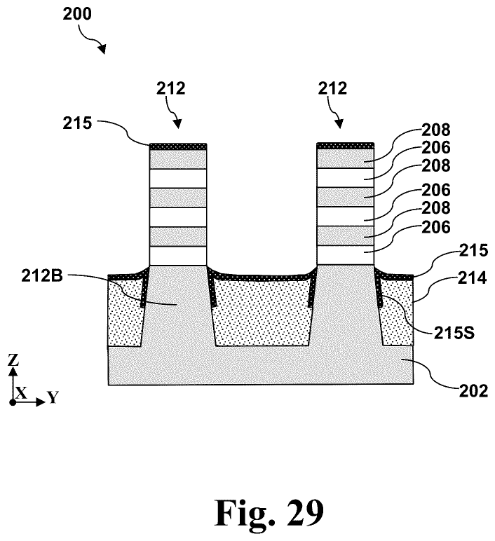

Referring to FIGS. 25 and 29, method 300 includes a block 308 where the sacrificial liner 211 and the mask layer 213 are selectively removed. In some embodiments, a wet etch process may be used to remove both the sacrificial liner 211 and the mask layer 213 over the sacrificial liner 211. In some instances, the wet etch process may include use of an ammonium hydroxide (NH₄OH) solution or a mixture of ammonium hydroxide, hydrogen peroxide and water at a process temperature greater than room temperature but lower than a boiling point of water, such as between 45° C. and about 70° C.

Referring to FIGS. 25, 29 and 30, method 300 includes a block 310 where the protection layer 215 is deposited over the fin-shaped structure 212 and the isolation feature 214. After the removal of the sacrificial liner 211 and the mask layer 213, the protection layer 215 may be deposited on top facing surfaces of the fin-shaped structures 212 and the isolation feature 214. As shown in FIG. 29, the protection layer 215 is also deposited into the crevices 2140 (shown in FIG. 28), thereby forming a sidewall protection layer 215S. The formation and the composition of the protection layer 215 is similar to the protection layer 215 described above in block 108. Detailed description of the protection layer 215 is omitted here for brevity.

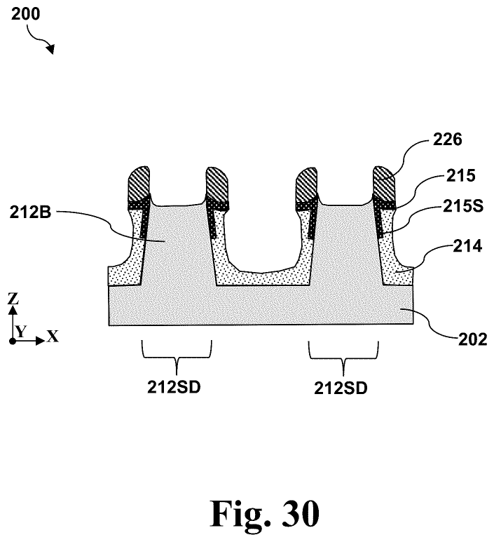

Reference is made to FIG. 30, which includes a fragmentary cross-sectional view across two adjacent source/drain regions 212SD. As shown in FIG. 30, the sidewall protection layer 215S extends along the base fin structure 212B is present and visible in the source/drain regions 212SD.

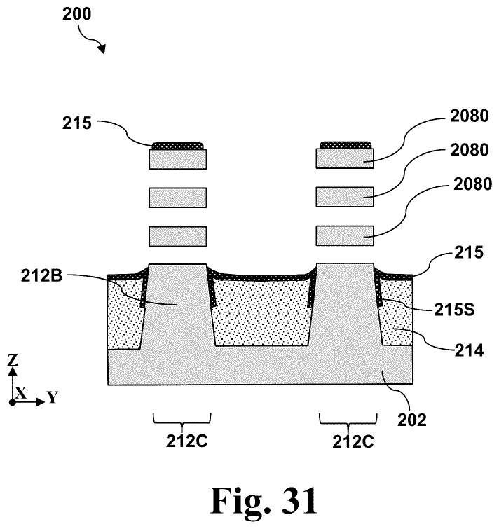

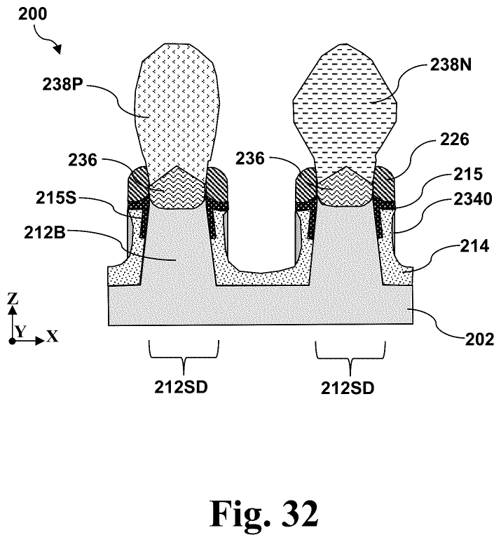

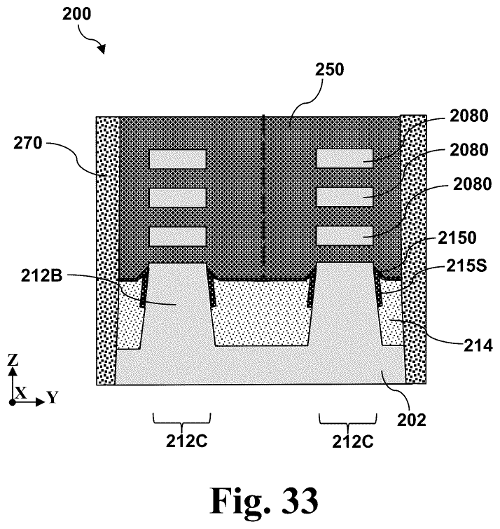

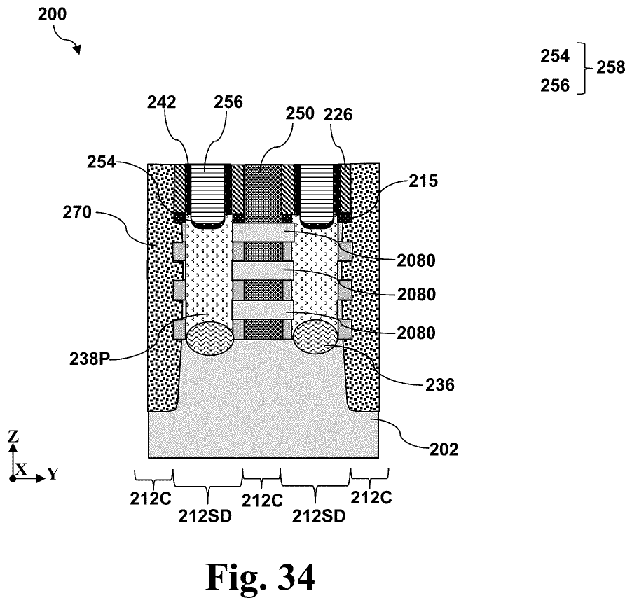

FIGS. 31-34 illustrates fragmentary cross-sectional views of the WIP structure 200 undergoing operations at blocks 124 and 126 when the sidewall protection layer 215S is present. Referring to FIG. 31, after the dummy gate stack 220 and the dummy layer 230 over the channel regions 212C are removed, the channel members 2080 are released again. The sidewall protection layer 215S extends along a top portion of the base fin structure 212B to protect the isolation feature 214 from undesirable damages. Referring to FIGS. 32 and 33, the sidewall protection layer 215S remain present in in the source/drain region 212SD and the channel region 212C to protect the sidewall of the isolation feature 214 after formation of the source/drain feature 240 and the gate structure 250. The protection layer 215 may be largely removed during the removal of the dummy layer 230 at block 124, leaving behind only the bottom protection layer 2150. FIG. 34 illustrates absence of the sidewall protection layer 215S along a cross-section along a lengthwise direction of the fin-shaped structure 212.

Method 100 includes block 108 to form the protection layer 215 on top surfaces of the isolation feature 214. The protection layer 215 formed in method 100 protects the top surfaces of the isolation feature 214 but does not protect any part of the sidewalls of the isolation feature 214. Method 400 in FIG. 35 includes operations that replace block 108 such that the protection layer 215 works in synergy with a liner 209 to protect the isolation feature 214.

Referring to FIGS. 35 and 36, method 400 includes a block 402 where a liner 209 is deposited over the fin-shaped structure 212. After formation of the fin-shaped structures 212 and before formation of the isolation feature, the liner 209 is deposited over the WIP structure 200, including along top surfaces and sidewalls of the fin-shaped structure 212, sidewalls of the base fin structures 212B, and a top surface of the substrate 202. In some embodiments, the liner 209 may include silicon nitride and may be deposited over the WIP structure 200 using CVD or ALD.

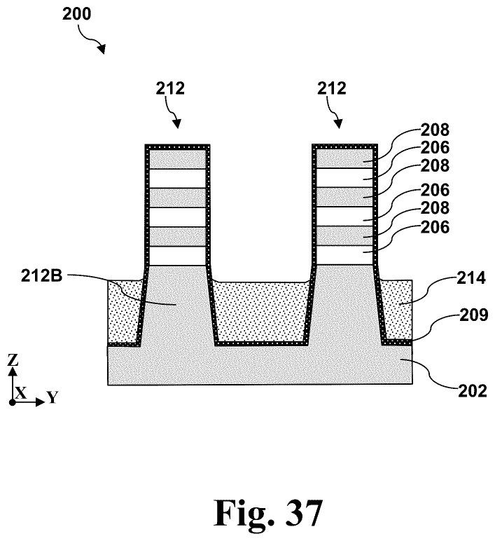

Referring to FIGS. 35 and 37, method 400 includes a block 404 where an isolation feature 214 is formed over the liner 209 to surround the base portion of the fin-shaped structure 212. With the exception that the isolation feature 214 is formed after the formation of the liner 209, operations at block 404 are substantially similar to those described above with respect to block 106. Detailed description of the isolation feature 214 is omitted here for brevity. As shown in FIG. 36, the isolation feature 214 is spaced apart from the substrate 202 and the base fin structures 212B by the liner 209.

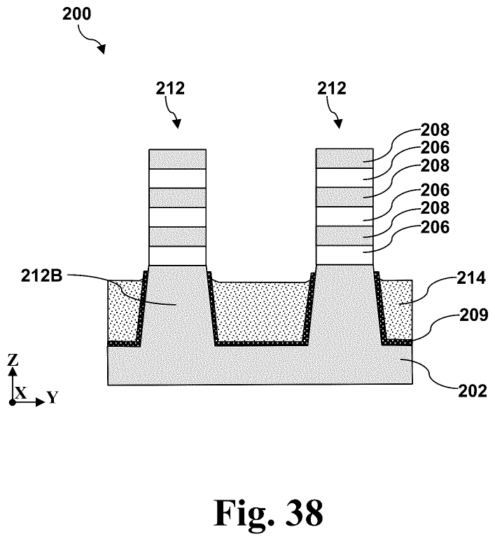

Referring to FIGS. 35 and 38, method 400 includes a block 406 where the liner 209 not covered by the isolation feature 214 is trimmed. The trimming of the liner 209 may be achieved using a selective dry etch process or a selective wet etch process. An example selective dry etch process may include carbon tetrafluoride (CF₄), nitrogen trifluoride (NF₃), oxygen (O₂), nitrogen (N₂), or a combination thereof. An example selective wet etch process may include use of warm phosphoric acid (H₃PO₄). As shown in FIG. 37, the trimming at block 404 removes the liner 209 from the top surfaces and sidewalls of the fin-shaped structures 212.

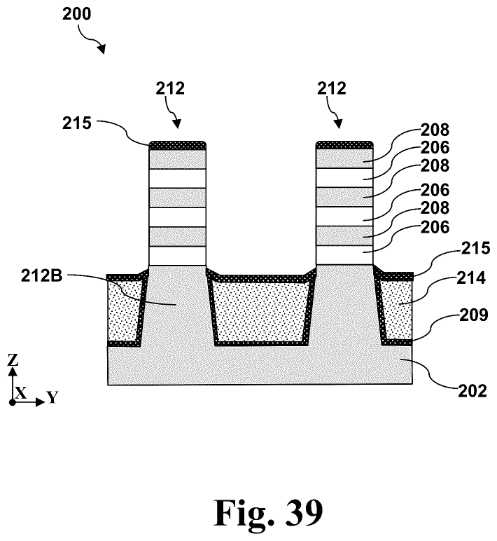

Referring to FIGS. 35 and 39, method 400 includes a block 408 where the protection layer 215 is deposited over the fin-shaped structure 212 and the isolation feature 214. After the trimming of the liner 209, the protection layer 215 may be deposited on top facing surfaces of the fin-shaped structures 212, the liner 209, and the isolation feature 214. As shown in FIG. 38, the protection layer 215 may overlap with or contact the liner 209 to substantially wrap around the isolation feature 214. The formation and the composition of the protection layer 215 is similar to the protection layer 215 described above in block 108. Detailed description of the protection layer 215 is omitted here for brevity.

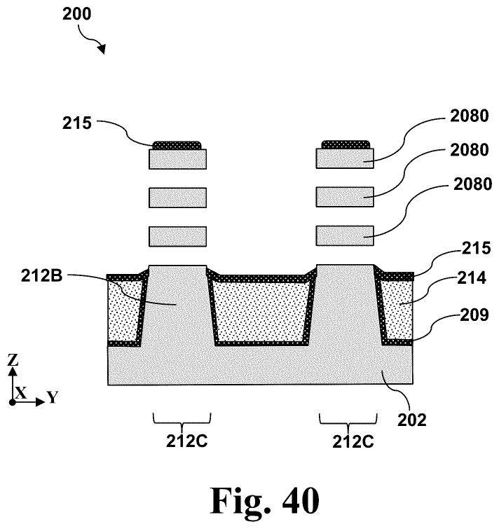

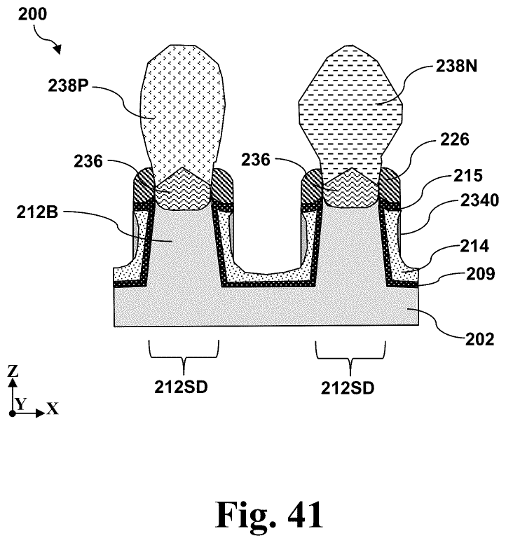

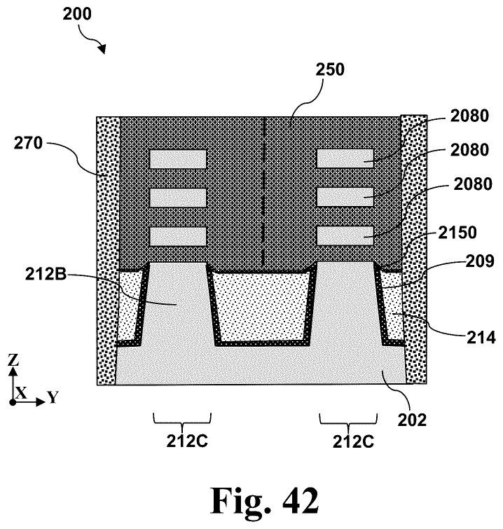

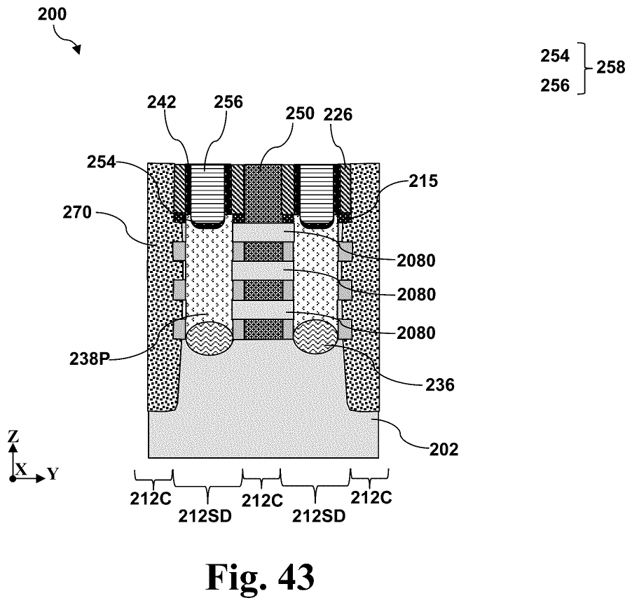

FIGS. 40-43 illustrates fragmentary cross-sectional views of the WIP structure 200 undergoing operations at blocks 124 and 126 when the liner 209 is present. Referring to FIG. 40, after the dummy gate stack 220 and the dummy layer 230 over the channel regions 212C are removed, the channel members 2080 are released again. The liner 209 extends along sidewalls of the base fin structure 212B and merge with the protection layer 215 on the top surface of the isolation feature 214. The liner 209 and the protection layer 215 work in synergy to protect the isolation feature 214 from undesirable damages. The protection layer 215 over the top surface of the topmost channel member 2080 is removed before the formation of the gate structure 250. FIG. 41 illustrates that the liner 209 extends along sidewalls of the base fin structures 212B in the source/drain regions 212SD. In FIG. 41, a portion of the protection layer 215 is sandwiched between the isolation feature 214 and the gate spacer layer 226. FIG. 42 illustrates that the liner 209 extends along sidewalls of the base fin structures 212B in the channel regions 212C. Besides the liner 209, incomplete removal of the protection layer 215 over the isolation feature 214 results in the bottom protection layer 2150. FIG. 43 illustrates absence of the liner 209 along a cross-section along a lengthwise direction of the fin-shaped structure 212.

Method 100 includes block 108 to form the protection layer 215 directly on top surfaces of the isolation feature 214. Method 500 in FIG. 44 includes operations that replace block 108 such that the protection layer 215 is spaced apart from the isolation feature 214 by an interface layer 217. Method 500 is useful if unwanted charges and traps at an interface of the protection layer 215 and the channel layers 208 are a concern. The interface layer 217 spaces the protection layer 215 away from the fin-shaped structure 212.

Referring to FIGS. 44, 45 and 46, method 500 includes a block 502 where an interface layer 217 is deposited over the fin-shaped structure 212 and the isolation feature 214. A composition of the interface layer 217 is different from that of the protection layer 215. In some embodiments, the interface layer 217 may include silicon oxide and may be conformally deposited over the fin-shaped structures 212 and the isolation feature 214 using ALD or CVD.

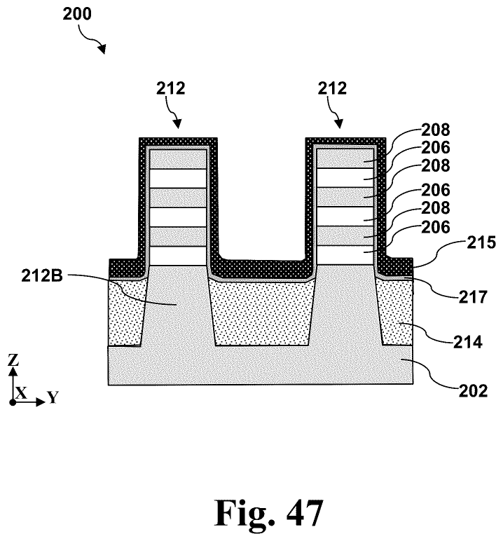

Referring to FIGS. 44 and 47, method 500 includes a block 504 where a protection layer 215 is deposited over the interface layer 217. In some embodiments, the protection layer 215 includes silicon nitride, silicon oxycarbonitride, aluminum oxide, or a combination thereof. In one embodiment, the protection layer 215 includes silicon nitride. Different from the protection layer 215 deposited at block 108 of method 100, the protection layer 215 is deposited over the top surface of the isolation feature 214, sidewalls of the fin-shaped structures 212, and top surfaces of the fin-shaped structures 212 using CVD or PVD without the subsequent etch back process. Because the top-facing surfaces are more in the line of sight, the protection layer 215 over the top-facing surfaces is thicker than the protection layer 215 disposed along sidewalls of the fin-shaped structures 212.

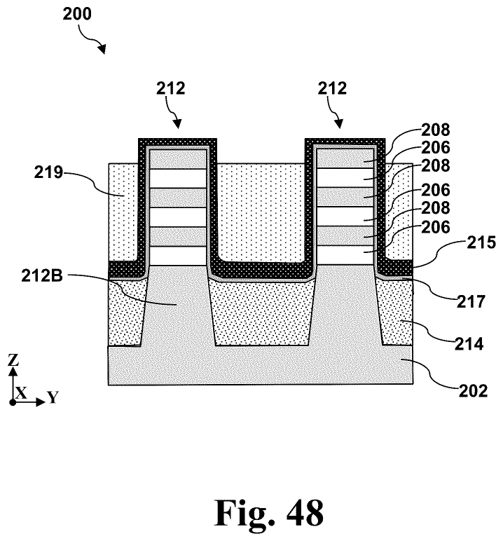

Referring to FIGS. 44 and 48, method 500 includes a block 506 where a bottom antireflective coating (BARC) layer 219 is deposited over the protection layer 215. In some implementations, the BARC layer 219 may include silicon oxynitride (SiON), silicon oxycarbide, a polymer, or other suitable materials. In some implementations, the BARC layer 219 may be deposited over the protection layer 215 using CVD, spin-on processes, or other suitable processes.

Referring to FIGS. 44 and 48, method 500 includes a block 508 wherein the BARC layer 219 is etched back. After the deposition of the BARC layer 219, it is etched back to expose a portion of the protection layer 215. The etching back at block 506 may include use of a dry etch process. The dry etch process may include use of plasma of argon (Ar), oxygen (O₂), nitrogen (N₂), hydrogen (H₂), or a combination thereof.

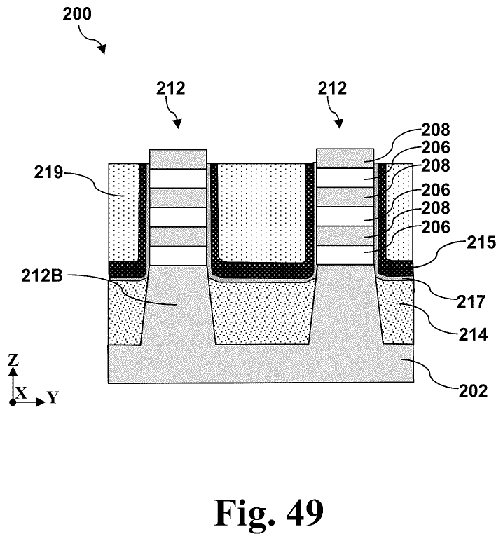

Referring to FIGS. 44 and 49, method 500 includes a block 510 wherein the protection layer 215 not covered by the BARC layer 219 is trimmed. In some embodiments represented in FIG. 48, the trimming of the protection layer 215 also etches the interface layer 217. In some embodiments, the trimming may include use of an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 48, the trimming exposes at least a portion of the topmost channel layers 208.

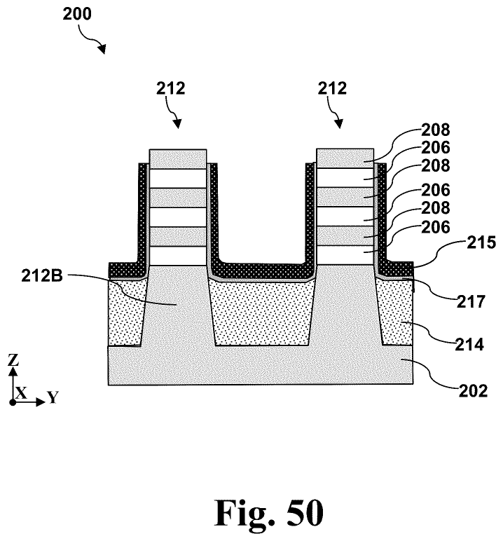

Referring to FIGS. 44 and 50, method 500 includes a block 512 wherein the BARC layer 219 is removed. At block 512, the rest of the BARC layer 219 may be removed using an ashing process or a dry etch process that includes use of plasma of argon (Ar), oxygen (O₂), nitrogen (N₂), hydrogen (H₂), or a combination thereof.

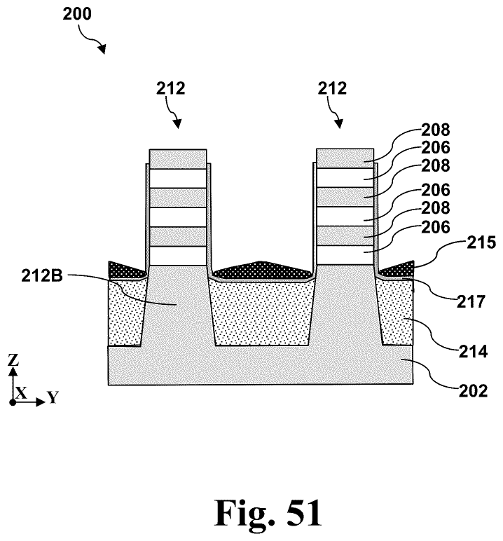

Referring to FIGS. 44 and 51, method 500 includes a block 514 wherein the protection layer 215 over sidewalls of the fin-shaped structure 212 is removed. In some embodiments, an isotropic process, such as a wet etch process, is used at block 514. An example wet etch process may include use of a warm phosphoric acid (H₃PO₄). As described above, because the protection layer 215 along the sidewalls of the fin-shaped structures 212 are thinner than the counterpart over the isolation feature 214, the protection layer 215 along the sidewalls of the fin-shaped structures 212 may be completely removed while a portion of the protection layer 215 over the isolation feature 214 remains. Because the isotropic etch process at block 514 etches the protection layer 215 near the interface layer 217, a center hill profile shown in FIG. 51 may be formed. That is, when viewed along a lengthwise direction (i.e., X direction) of the fin-shaped structures 212, the protection layer 215 is thicker in the middle and thinner closer to the interface layer 217.

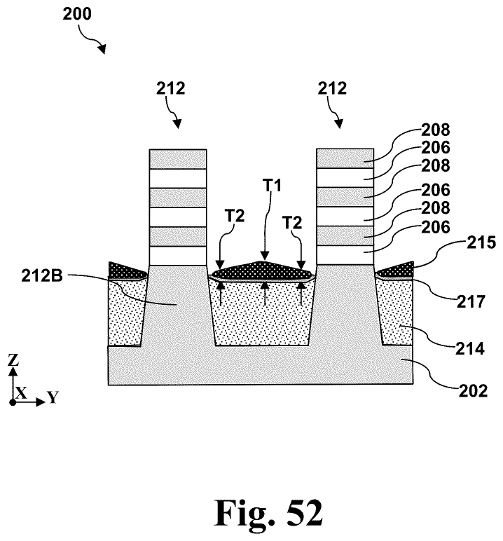

Referring to FIGS. 44 and 52, method 500 includes a block 516 wherein the interface layer 217 over sidewalls of the fin-shaped structure 212 is selectively removed. In some embodiments where the interface layer 217 includes silicon oxide, the interface layer 217 not covered by the protection layer 215 may be selectively removed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof. As shown in FIG. 52, because the interface layer 217 not covered by the protection layer 215 extends along sidewalls of the fin-shaped structures 212, the selective removal at block 516 exposes sidewalls of the fin-shaped structures 212.

Reference is still made to FIG. 52. Because the protection layer 215 is substantially unharmed at block 516, the center hill profile described above may remain. In some embodiments represented in FIG. 52, the protection layer 215 includes a first thickness T1 at equal distance to the two base fin structures 212B and a second thickness T2 closer to the two base fin structures 212B. The first thickness T1 is greater than the second thickness T2.

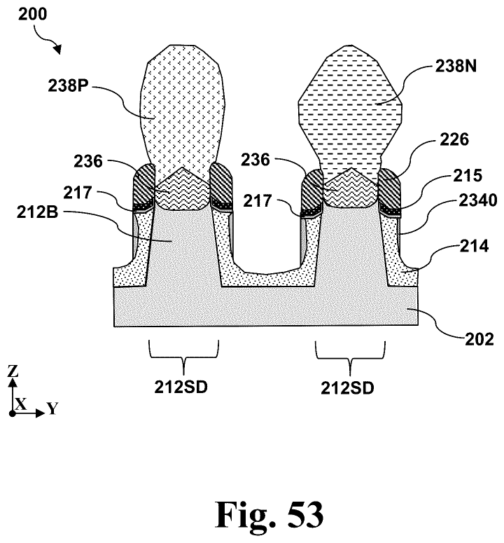

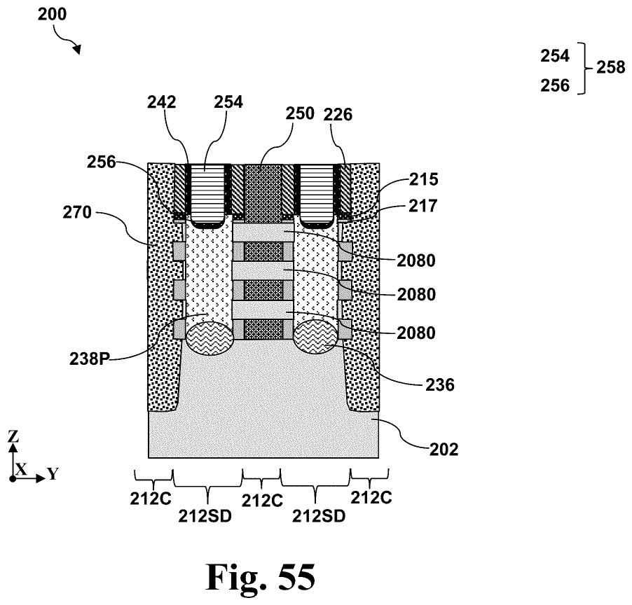

FIGS. 53-55 illustrates fragmentary cross-sectional views of the WIP structure 200 undergoing operations at blocks 124 and 126 when the protection layer 215 is spaced apart from the isolation feature 214 by the interface layer 217. FIG. 53 illustrates that in the source/drain regions 212SD, the protection layer 215 is spaced apart from the isolation feature 214 and the sidewall portion 2340 of the inner spacer feature 234 by the interface layer 217. The interface layer 217 is also sandwiched between the base fin structures 212B and the protection layer 215. FIG. 53 illustrates that in some embodiments, the gate structure 250 may be spaced apart from the isolation feature 214 by the protection layer 215 and the interface layer 217. In the depicted embodiment, the gate structure 250 is in contact with the interface layer 217 and the protection layer 215. FIG. 55 illustrates that, under the gate spacer layer 226, the protection layer 215 is spaced apart from the top surfaces of the topmost channel members 2080 by the interface layer 217.

In one exemplary aspect, the present disclosure is directed to a semiconductor structure. The semiconductor structure includes an isolation feature, a first base fin and a second base fin extending through and rising above the isolation feature, a first active region disposed over the first base fin, a second active region disposed over the second base fin; a gate structure disposed over the first active region, the second active region, and the isolation feature, and a protection layer sandwiched between the gate structure and the isolation feature.

In some embodiments, the isolation feature includes silicon oxide and the protection layer includes silicon nitride. In some embodiments, the first active region includes a first plurality of nanostructures disposed one over another and the second active region includes a second plurality of nanostructures disposed one over another. In some embodiments, the gate structure wraps around each of the first plurality of nanostructures and the second plurality of nanostructures. In some implementations, the protection layer includes a portion that extends between a sidewall of the first base fin and the isolation feature and between a sidewall of the second base fin and the isolation feature. In some embodiments, the protection layer is spaced apart from the isolation feature by an interface layer. In some embodiments, the interface layer incudes silicon oxide. In some instances, the first base fin is spaced apart from the second base fin along a direction and the gate structure is sandwiched between a first dielectric fin and a second dielectric fin along the direction. In some instances, the first dielectric fin and the second dielectric fin extend into the isolation feature.

In another exemplary aspect, the present disclosure is directed to a semiconductor structure. The semiconductor structure includes a first base fin and a second base fin spaced apart from one another along a direction, a first source/drain feature disposed over the first base fin, a second source/drain feature disposed over the second base fin, an isolation feature disposed between the first base fin and the second base fin along the direction and extending along a sidewall of the first base fin and a sidewall of the second base fin, a first gate spacer feature in contact with a sidewall of the first source/drain feature, a second gate spacer feature in contact with a sidewall of the second source/drain feature, a first portion of a protection layer sandwiched between the first gate spacer feature and the isolation feature, and a second portion of the protection layer sandwiched between the second gate spacer feature and the isolation feature.

In some embodiments, the isolation feature includes silicon oxide and the protection layer includes silicon nitride. In some embodiments, the first source/drain feature includes silicon germanium (SiGe) and a p-type dopant, and the second source/drain feature includes silicon (Si) and an n-type dopant. In some embodiments, the first gate spacer feature and the second gate spacer feature include silicon oxycarbonitride. In some embodiments, the semiconductor structure further includes a first plurality of nanostructures coupled to the first source/drain feature, a second plurality of nanostructures coupled to the second source/drain feature, and a gate structure wrapping around each of the first plurality of nanostructure and the second plurality of nanostructures.

In yet another exemplary aspect, the present disclosure is directed to a method. The method includes forming over a substrate a stack that includes a plurality of channel layers interleaved by a plurality of sacrificial layers, patterning the stack and the substrate to form a fin-shaped structure having a base portion formed from the substrate and a stack portion formed from the stack, forming an isolation feature around the base portion, depositing a protection layer over a top surface of the isolation feature and a top surface of the fin-shaped structure, forming a dummy gate stack over a channel region of the fin-shaped structure, depositing a gate spacer layer over the dummy gate stack, recessing a source/drain region of the fin-shaped structure, selectively removing the plurality of sacrificial layers in the channel region to release the plurality of channel layers as a plurality of channel members, depositing a dummy layer over the channel members, selectively and partially recessing the dummy layer to form inner spacer recesses among the plurality of channel members, forming inner spacer features in the inner spacer recesses, forming a source/drain feature over the source/drain region, and replacing the dummy gate stack and the dummy layer with a gate structure.

In some embodiments, the protection layer includes silicon nitride. In some embodiments, the depositing of the protection layer includes depositing the protection layer and isotropically etching back the deposited protection layer. In some implementations, after the depositing of the protection layer, sidewalls of the fin-shaped structure are free of the protection layer. In some embodiments, the dummy layer includes silicon oxide. In some embodiments, the depositing of the dummy layer includes depositing a first dummy layer using atomic layer deposition (ALD) and depositing a second dummy layer over the first dummy layer using flowable chemical vapor deposition (FCVD).

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
an isolation feature disposed over the substrate;
a first base fin and a second base fin extending from the substrate and through the isolation feature;
first channel members over the first base fin;
second channel members over the second base fin;
a protection layer over the isolation feature; and
a gate structure wrapping around the first channel members and the second channel members,
wherein the gate structure interfaces the protection layer,
wherein the protection layer disposed between the first base fin and the second base fin comprises a center hill profile such that a thickness of a center portion of the protection layer equidistant from the first base fin and the second base fin is greater than a thickness of an end portion of the protection layer adjacent the first base fin or the second base fin.

2. The semiconductor structure of claim 1, wherein the protection layer exerts a tensile strain and has a dielectric constant between about 6 and about 7.

3. The semiconductor structure of claim 1, wherein the protection layer comprises silicon nitride, silicon oxycarbonitride, or aluminum oxide.

4. The semiconductor structure of claim 1, further comprising:
an interface layer between the protection layer and a top surface of the isolation feature.

5. The semiconductor structure of claim 4, wherein a composition of the protection layer is different from a composition of the interface layer.

6. The semiconductor structure of claim 1, wherein the isolation feature interfaces sidewalls of the first base fin and the second base fin.

7. The semiconductor structure of claim 1, wherein top surfaces of the first base fin and the second base fin are higher than a top surface of the isolation feature.

8. The semiconductor structure of claim 1, further comprising:
a first source/drain feature disposed over the first base fin and interfacing end sidewalls of the first channel members; and
a second source/drain feature disposed over the second base fin and interfacing end sidewalls of the second channel members,
wherein the first source/drain feature comprises silicon germanium and a p-type dopant,
wherein the second source/drain feature comprises silicon and an n-type dopant.

9. The semiconductor structure of claim 8, further comprising:
a first bottom epitaxial layer disposed between the first base fin and the first source/drain feature; and
a second bottom epitaxial layer disposed between the second base fin and the second source/drain feature.

10. The semiconductor structure of claim 9, wherein the first bottom epitaxial layer and the second bottom epitaxial layer comprise undoped silicon or undoped silicon germanium.

11. A semiconductor structure, comprising:
a substrate;
an isolation feature disposed over the substrate;
a first base fin and a second base fin extending from the substrate and through the isolation feature, the first base fin comprising a first channel region and a first source/drain region and the second base fin comprising a second channel region and a second source/drain region;
first channel members over the first channel region;
second channel members over the second channel region;
a protection layer over the isolation feature;
an interface layer disposed between the protection layer and the isolation feature; and
a gate structure wrapping around the first channel members and the second channel members,
wherein the gate structure interfaces the protection layer,
wherein the first base fin and the second base fin extend lengthwise along a first direction,
wherein the protection layer between the first channel region and the second channel region comprises a convex profile when viewed along the first direction.

12. The semiconductor structure of claim 11, wherein the protection layer comprises silicon nitride, silicon oxycarbonitride, or aluminum oxide.

13. The semiconductor structure of claim 11,
wherein the isolation feature comprises a first portion disposed between the first channel region and the second channel region and a second portion disposed between the first source/drain region and the second source/drain region,
wherein a top surface of at least a portion of the second portion is free of the interface layer or the protection layer.

14. The semiconductor structure of claim 11, further comprising:
a first bottom epitaxial layer over the first source/drain region;
a first source/drain feature over the first bottom epitaxial layer;
a second bottom epitaxial layer over the second source/drain region; and
a second source/drain feature over the second bottom epitaxial layer,
wherein the first bottom epitaxial layer and the second bottom epitaxial layer comprise undoped silicon or undoped silicon germanium.

15. The semiconductor structure of claim 14,
wherein the first source/drain feature comprises silicon germanium and a p-type dopant,
wherein the second source/drain feature comprises silicon and an n-type dopant.

16. The semiconductor structure of claim 14, further comprising:
a gate spacer disposed over the isolation feature and extending along a sidewall of the first bottom epitaxial layer and a sidewall of the first source/drain feature,
wherein the gate spacer is spaced apart from the isolation feature by the interface layer and the protection layer.

17. A semiconductor structure, comprising:
a substrate;
an isolation feature disposed over the substrate;
a first base fin and a second base fin extending from the substrate and through the isolation feature, the first base fin being spaced apart from the second base fin along a direction;
first channel members over the first base fin;
second channel members over the second base fin;
a protection layer over the isolation feature; and
a gate structure wrapping around the first channel members and the second channel members,
wherein the gate structure interfaces the protection layer,
wherein the gate structure is disposed between a first dielectric feature and a second dielectric feature along the direction,
wherein the first dielectric feature and the second dielectric feature extend through the protection layer, the isolation feature, and a portion of the substrate,
wherein the protection layer disposed between the first base fin and the second base fin comprises a center hill profile such that a thickness of a center portion of the protection layer equidistant from the first base fin and the second base fin is greater than a thickness of an end portion of the protection layer adjacent the first base fin or the second base fin.

18. The semiconductor structure of claim 17, wherein the protection layer comprises silicon nitride, silicon oxycarbonitride, or aluminum oxide.

19. The semiconductor structure of claim 17, further comprising:
an interface layer between the protection layer and a top surface of the isolation feature,
wherein a composition of the protection layer is different from a composition of the interface layer.

20. The semiconductor structure of claim 17, wherein top surfaces of the first dielectric feature, the gate structure, and the second dielectric feature.
